(19) United States
(12) Patent Application Publication
(10) Pub. No.: US 2025/0045487 A1
(43) Pub. Date: Feb. 6, 2025

(54) METHOD OF DETERMINING ACOUSTIC PARAMETERS OF AN OBJECT'S EMISSION, COMPUTER PRODUCT, SYSTEM

(71) Applicant: Siemens Industry Software NV, Leuven (BE)

(72) Inventor: Onur Atak, Cambridge (GB)

(21) Appl. No.: 18/718,057

(22) PCT Filed: Oct. 7, 2022
(86) PCT No.: PCT/EP2022/077934

§ 371 Date: Jun. 9, 2024

(30) Foreign Application Priority Data
Dec. 9, 2021 (EP) 21213424.1

(51) Int. Cl. G06F 30/23

(52) U.S. Cl. CPC G06F 30/23

(57) ABSTRACT

Method of determining acoustic parameters of an object's (OBJ) emission and/or scattering, in particular for improving acoustic properties of said object (OBJ), comprising: (a) defining a model (MDL) including said object (OBJ), a sound source (SCR), and a surrounding area, (b) processing said model (MDL) obtaining a result (RST), (c) post-processing the result (RST) by assigning to said field points (PTS) at least one parameter (PRM) determined from calculating the Helmholtz-Kirchhoff integral from said result (RST). To improve the accuracy and efficiency the post-processing comprises the additional steps: (d) identifying field points (PTS) as near field singularity field points (NEP) of potential lower result (RST) accuracy (ACR), (c) determining for said near field singularity field points (NEP) respectively an associated model mesh element (AME), by determining a local projection from said near field singularity field point (NEP) to the object's (OBJ) surface by calculating a minimum normal distance (MND) to the object's (OBJ) surface, wherein the associated model mesh element (AME) being the touchdown point of the local projection, (f) determining for said near field singularity field points (NEP) respectively a ratio (RTO) of the minimum normal distance (MND) to said element size (ESZ) of the associated model mesh element (AME), (g) calculating the Helmholtz-Kirchhoff integral by: (g11) providing a relation (PCR) of quadrature order (QOD) and said ratio (RTO), (g2) determine the respective quadrature order (QOD) by applying said relation (PCR), (g3) calculating the Helmholtz-Kirchhoff integral from said result (RST).

### FIELD OF THE INVENTION

The invention relates to a method of determining acoustic parameters of an object's emission and/or scattering, in particular for improving acoustic properties of said object, comprising:
(a) defining a model including said object, a sound source, and a surrounding area of modelling, said model including a model mesh comprising field points, wherein each field point belongs to an element of specific element size,
(b) processing said model obtaining a result,
(c) post-processing the result by assigning to said field points at least one parameter determined from calculating the Helmholtz-Kirchhoff integral from said result.

Further the invention relates to a system. The steps (a) and (b), in particular step (b), may preferably be automized, controlled by a computer or completely computer implemented.

### BACKGROUND OF THE INVENTION

Digitalization and the use of Computer-aided engineering [CAE] methods to solve real life engineering problems is well established today and keeps getting expanded to new users. Numerical Acoustics is a field that is also benefitting from this momentum. Engineers are using CAE methods to predict and design their products and improve the acoustic properties as a result.

The two most prominent numerical methods that are used in Numerical Acoustics field are the Finite Element Method [FEM] and the Boundary Element Method [BEM]. Both methods are most typically used to solve a steady-state problem of acoustics, which is conveniently solved in the frequency domain.

In general, a boundary value problem is set up in these cases. This process involves setting up the boundary conditions of the system, defining the excitation and solving the system of equations. Once the equations of unknowns are solved, a post-processing step is necessary to retrieve the acoustic quantities in the vicinity of the object. Such acoustic quantities are acoustic pressure, acoustic velocity, Sound Pressure Level [dB], A-weighted Sound Pressure Level [dBA], etc.

In the terminology of the invention a field point is a location with defined spatial coordinates, which is one field point of interest where the acoustic quantities are being calculated at. Acoustic velocity is the velocity at which a small disturbance propagates through a medium. The acoustic velocity is related to the change in pressure and density of the substance. The speed of sound herein means a medium property depending on temperature and matter properties. Each field point may be assigned to a specific element of specific size, wherein said element may be a 2-dimensional or 3-dimensional surface or volume.

The object emitting or scattering can be any object, like a car, vehicle, train, aircraft or component of such or a stationary object like a building or a machine emitting any sound. The surface of this object may be meshed during the process

In the context of the invention parent elements are ideal elements—like reference elements—of a specific type. Parent elements may be e.g., triangular or quadrilateral. When being applied to a structure these ideal geometry is changed into the specific geometrical requirements to fit the structure.

The post-processing step can be done in two different forms. The method of choice depends on the numerical method being used and the configuration of the problem. For FEM, if the field point lies within the model mesh, interpolating the nodal quantities is sufficient.

The technical focus of the invention lies mainly on the second form, which is post-processing of the BEM field points or of FEM models when the field points of interest lie outside of the model mesh. The latter happens when FEM is being used to solve unbounded acoustic configurations, i.e., when the acoustic waves are propagating to infinity. In such problems, special boundary conditions are applied to absorb the outgoing waves and a post-processing step is required for FEM that is similar to BEM.

This second form of the post-processing step requires the calculation of a surface integral that is known as the Helmholtz-Kirchhoff integral. The inputs to the integral are the acoustic pressure and acoustic velocity on the model mesh which are the two main variables of the governing equation on an enclosed surface. The output received from the Helmholtz-Kirchhoff integral is the acoustic pressure at the field point.

The main problem with calculating the Helmholtz-Kirchhoff integral is that it uses the fundamental solution of the governing equation, which is known as the Green's function. This function has a 1/r dependency, where r is the distance between the source or source center point and the field point. In other words, it is a function with r singularity. Due to this issue, the Helmholtz-Kirchhoff integral becomes polluted as r gets closer to zero. In practice, this would mean that the acoustic results for the field points that are very close to the surface of the Helmholtz-Kirchhoff integral are inaccurate. One example of an industrial application with such issue is e.g., a pressure field around a car body. In the areas close to the car body respectively these near field singularity hotspots build up which are a symptom of a bad accuracy showing non-physical results of the non-treated singularity problem. This unsolved problem is of specific disadvantage since the acoustic information close to the modelling object is of high importance for respective customer, the car manufacturer and finally to the engineers. The demand of a smooth solution correctly reflecting the real physics is needed.

The aforementioned issue is known as the Near Field Singularity or as the Nearly Singular Integral problem in literature and over the years, it has attracted a lot of attention from the scientific community.

A less complex approach is to increase the number of quadrature points used for the surface integral. This may be classified as a brute force approach. When the field point is not in the immediate vicinity of the surface, this approach may be successful. On the other hand, with increasing proximity of the field point, thousands of quadrature points per element and per target field point are required. As such, this approach may become costly in terms of computational time and becomes impractical for industrial scale problems.

The general philosophy to properly solve such a nearly singular surface integral is to find a suitable coordinate transformation for the quadrature points that will make the integral manageable. The following publications suggest some approaches [1-5].
[1] Johnston, P. R., Johnston, B. M., & Elliott, D. (2013). Using the iterated sinh transformation to evaluate two dimensional nearly singular boundary element integrals. Engineering Analysis with Boundary Elements, 37(4), 708-718.
[2] Keuchel, S., Hagelstein, N. C., Zaleski, O., & von Estorff, O. (2017). Evaluation of hypersingular and nearly singular integrals in the Isogeometric Boundary Element Method for acoustics. Computer Methods in Applied Mechanics and Engineering, 325, 488-504.
[3] Gu, Y., Chen, W., & Zhang, C. (2013). The sinh transformation for evaluating nearly singular boundary element integrals over high-order geometry elements. Engineering Analysis with Boundary Elements, 37(2), 301-308.
[4] Lv, J., Miao, Y., & Zhu, H. (2014). The distance sinh transformation for the numerical evaluation of nearly singular integrals over curved surface elements. Computational Mechanics, 53(2), 359-367.
[5] Gu, Y., Gao, H., Chen, W., Wang, H., & Zhang, C. (2017). A general algorithm for evaluating nearly strong-singular (and beyond) integrals in three-dimensional boundary element analysis. Computational Mechanics, 59(5).

Currently a general and efficient method enabling to use low and high order curved elements of both quadrilateral and triangular shapes is not available.

### SUMMARY OF THE INVENTION

Based on the shortcomings of the state of the art it is one object of the invention to enable the use of low and high order curved elements of both quadrilateral and triangular shapes.

It is another object of the invention to provide a method applicable to industrial scale problems. Such industrial scale may be understood as problems where both the number of elements on the model mesh and the number of field points are comparably high, e.g., at least 5.000 elements and/or field points up to 100s of thousands.

It is another object of the invention to improve the accuracy of post-processing results of the BEM field points or of FEM models.

The object of the invention is achieved by the independent claims. The dependent claims describe advantageous developments and modifications of the invention.

In accordance with the invention there is provided a solution for the above-described problems by the incipiently defined method with the additional steps:
(d) identifying field points as near field singularity field points of potential lower result accuracy,
(e) determining for said near field singularity field points (NFP) respectively an associated model mesh element (AME), by determining a local projection from said near field singularity field point (NFP) to the object's (OBJ) surface by calculating a minimum normal distance (MND) to the object's (OBJ) surface, wherein the associated model mesh element (AME) being the touchdown point of the local projection,
(f) determining for said near field singularity field points (NFP) respectively a ratio (RTO) of the minimum normal distance (MND) to said element size (ESZ) of the associated model mesh element (AME),
(g) calculating the Helmholtz-Kirchhoff integral by:
   (g1) providing a relation of quadrature order and said ratio,
   (g2) determine the respective quadrature order for said near field singularity field points by applying said relation,
   (g3) calculating the Helmholtz-Kirchhoff integral from said result.

With this invention a methodology has been developed that overcomes the above limitations and enables accurate acoustic results for the field points that are very close to the surface of the Helmholtz-Kirchhoff integral.

The invention proposes a method to handle Near Field Singularities in an efficient and accurate way for linear and quadratic versions of the triangular and quadrilateral surface elements.

According to a preferred embodiment the calculating of the Helmholtz-Kirchhoff integral from said result may comprise applying a coordinate transformation for solving the integral. A transformation may improve the accuracy and efficiency of the integration. In the preferred option when said model mesh provides quadrilateral object elements said coordinate transformation may combine an iterated sinh transformation method with an additional coordinate transformation projecting the quadrilateral object element space to a triangular object element space or vice versa.

According to still another preferred embodiment step (d) may comprise the additional steps of:
(d1) defining a threshold distance of said field points to the object,
(d2) assigning the field points to one of two groups:
   near field singularity field points, which are less than said threshold distance away from the object,
   standard field point, which are not near field singularity field points.

Basically, assigning the tag ‘standard field point’ may be considered as being already done by identifying the near field singularity field points since the standards field points are all field points which are not near field singularity field points. Classifying field points as standard field point results in the advantage of marking these field points as being classified instead of untreated.

To further increase efficiency and save computational resources identifying potential near field singularity field points may be done via an octree-based search algorithm applied to at least a part of the field points. This search may result in a reduced search space of potential near field singularity field points before the steps (d1), (d2) of are applied to this reduced search space. Most preferably before performing the more complex steps (‘search’, ‘threshold distance’) of identifying the near field singularity field points a less complex upper limit may be applied as a distance criterium to classify the far away field points to be standard field points, upfront.

Another preferred embodiment comprises a step of displaying said acoustic parameters and/or key figures calculated from said acoustic parameters or images illustrating said acoustic parameter fields to a user.

According to a preferred embodiment said acoustic parameters may be provided to an iterative object design process for designing acoustic emission. The user may be able to evaluate and compare the obtained acoustic parameters with results of different designs or boundary conditions based on the visualization of acoustic parameters.

According to still another preferred embodiment of the invention said acoustic parameters and/or key figures calculated from said acoustic parameters or images illustrating said acoustic parameter fields are displayed to a user and/or provided to an iterative object design process for improving acoustic emission.

The invention further relates to a computer product arranged and configured to execute the steps of the computer-implemented method as explained herein and as defined by the claims.

The invention further relates to a computer-readable medium encoded with executable instructions, that when executed, cause the computer product according to carry out a method according to the invention.

The invention further relates to a system for determining acoustic parameters of an object's emission, the system comprising at least one processor being prepared by upload of computer-executable code to perform a method according to the invention.

### BRIEF DESCRIPTION OF THE DRAWINGS

Embodiments of the invention are now described, by way of example only, with reference to the accompanying drawings, of which:

FIG. 1 shows a simplified flow diagram illustrating the method according to the invention as well as a system for performing the method;

FIG. 2, 3: respectively show key figures of acoustic parameters.

The illustration in the drawings is in schematic form.

It is noted that in different figures, similar or identical elements may be provided with the same reference signs.

### DESCRIPTION OF THE DRAWINGS

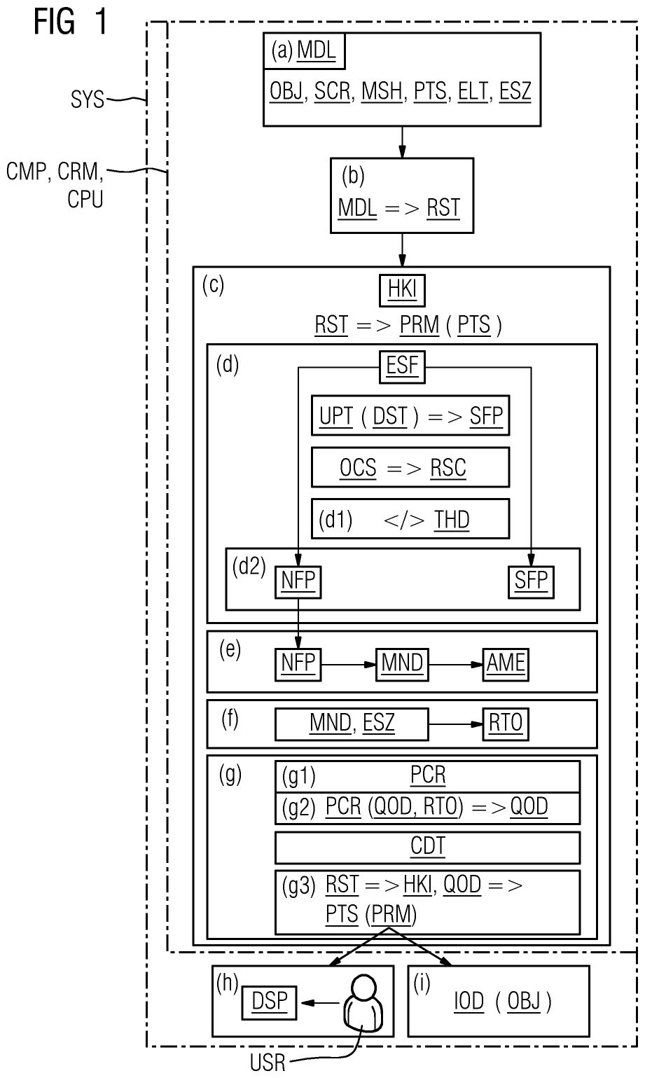

FIG. 1 shows a simplified flow diagram illustrating a method of determining acoustic parameters of an object's OBJ emission and scattering. FIG. 1 further illustrates a method for improving acoustic properties of said object.

Further, FIG. 1 illustrates a system SYS for determining acoustic parameters of an object's emission, the system SYS comprising at least one processor CPU being prepared by upload of computer-executable code to perform the method according to the invention. The method may be handled as a computer product CMP arranged and configured to execute the steps of the computer-implemented method according to the invention. Such computer product CMP may be a data storing media, like an optical or magnetic data storage or a download enablement e.g., a reading access of an URL where the respective data is provided to a user USR. Such data storage may be a computer-readable medium CRM encoded with executable instructions, that when executed, cause the computer product to carry out a method according to the invention.

As illustrated in FIG. 1, during a first step (a) said model MDL including said object OBJ, a sound source SCR, and a surrounding area of modelling are defined. Said model MDL includes a model mesh MSH on the object's surface. Each element ELT of the model mesh is of a specific element size ESZ.

The surrounding area is modelled by field points PTS of a field point cloud.

During the next step (b) the equations of unknowns of this problem are solved meaning that said model MDL is processed and a result RST is obtained. This solving process uses a suitable standard solver.

Subsequently a post-processing (c) of said result RST takes place. The goal of this step [RST=>PRM (PTS)] is to respectively assign at least one parameter PRM determined from calculating the Helmholtz-Kirchhoff integral HKI from said result RST to said field points PTS.

The following steps (d), (e), (f), (g) belong to the post-processing (c).

First—as a step (d)—field points PTS are identified as near field singularity field points NFP of potential lower result RST accuracy ACR.

To reduce the search space for near field singularity field points NFP starting from the complete surrounding area of modelling a reasonable upper threshold UPT of distance DST may be applied to exclude far away field points from the search space, which may be classified as standard field points SFP.

As a second measure of search space reduction an octree-based search algorithm OCS may be applied to at least a part of the field points PTS to further reduce the search space of potential near field singularity field points NFP before the steps (d1), (d2) of claim 4 are applied to this reduced search space RSC.

This basic process of search space reduction may be understood as:
The surface elements and field points are gathered in groups.
The faraway field points are quickly discarded from the search space. Once a group of field points and a group of elements are matched as potential near field singularity field points NFP and an associated model mesh element AME, a detailed search is done in this smaller search space.

So far this search space reduction is optional and serves the acceleration of the process.

The reduced search space (or the full search space) is then investigated by the additional steps of:
(d1) defining a threshold distance THD of said field points PTS to the object OBJ,
(d2) assigning the field points to one of two groups:
   near field singularity field points NFP, which are less than said threshold distance THD away from the object OBJ,
   standard field point SFP, which are not near field singularity field points NFP.

Of these resulting two groups the standard field points SFP are treated with standard gauss quadrature and the near field singularity field points NFP are treated specifically according to the invention.

During the subsequent step (e) an associated model mesh element AME is determined for said near field singularity field points NFP respectively. This is done by determining a local projection from said near field singularity field point NFP to the object's OBJ surface. The projection is based on calculating a minimum normal distance MND to the object's OBJ surface. The associated model mesh element AME is the touchdown point of this local projection. For flat surface elements, the projection can be calculated analytically. For curved surfaces, an iterative approach is required. The extreme value theorem and gradient method is used here.

Step (f) provides for each near field singularity field point NFP, determining a ratio RTO of the minimum normal distance MND to said element size ESZ of the associated model mesh element AME.

Based on a relation PCR—provided in step (g), (g1) returning a quadrature order QOD for ratio RTO value the quadrature order is defined for each near field singularity field point NFP. The relation preferably PCR provides an increasing quadrature order for increasing proximity [assuming constant element size] to the object's OBJ surface. The relation may provide for example a linear, quadratic, cubic or exponential relation between order and ratio. Another possibility may be an order assigned to a respective value range of said ratio. This adaptive quadrature order rule avoids using too many gauss points, hence avoids costly integrals. Applying the relation aims results in a good balance between accuracy versus computational cost.

Based on the relation PCR in step (g2) the respective quadrature order QOD for said near field singularity field points NFP is assigned.

Before calculating the Helmholtz-Kirchhoff integral from said result RST a coordinate transformation CDT is applied. Preferably—in case the model mesh MSH provides triangular object elements QOE [parent element space]—this coordinate transformation CDT combines an iterated sinh transformation method with an additional coordinate transformation projecting the triangular object element space to a quadrilateral object element space.

In step (g3) the Helmholtz-Kirchhoff integral from said result RST is calculated for each field point PTS assigning said acoustic parameter PRM to the field point PTS.

These acoustic parameters PRT and/or key figures KFG calculated from said acoustic parameters PRT or images illustrating said acoustic parameter fields may be displayed to a user USR by a display device DSP and/or may be provided said to an iterative object design process IOD for e.g., designing, improving, reducing, or optimizing acoustic emission.

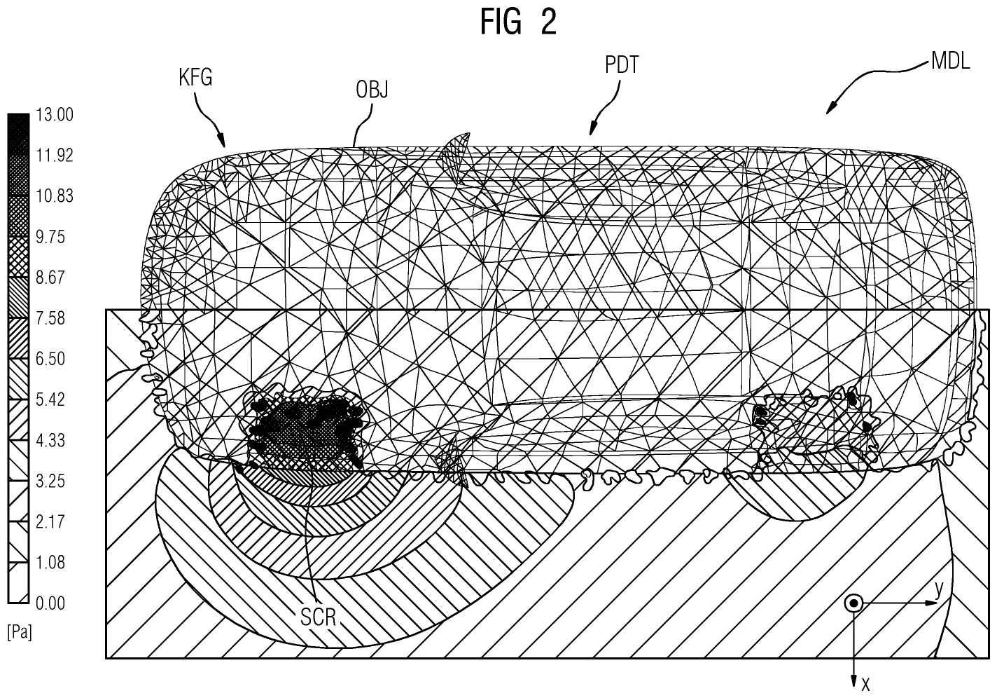

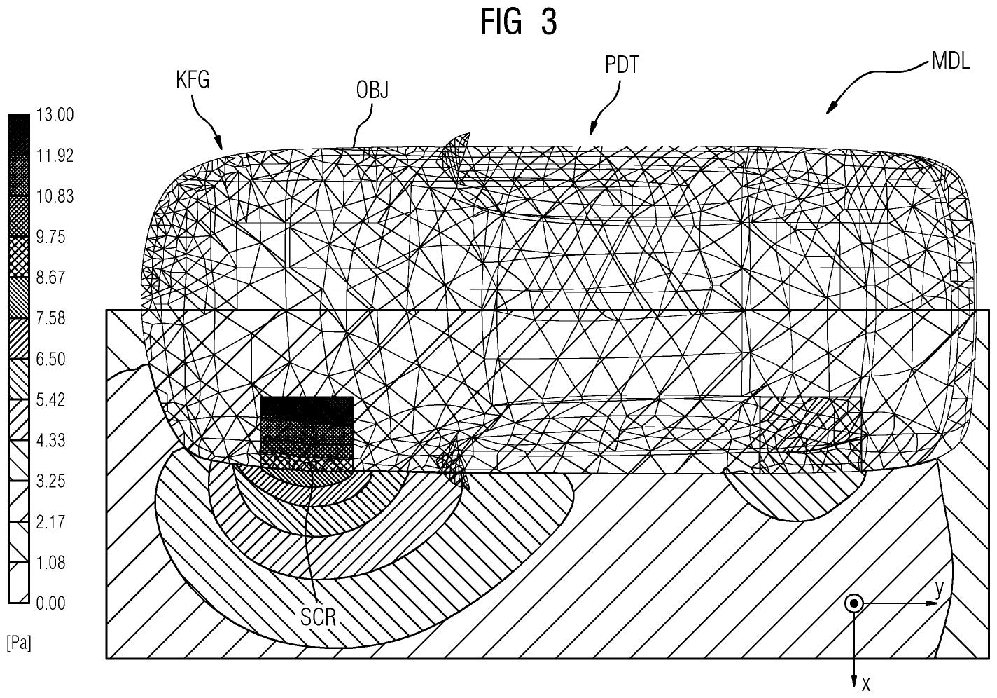

FIG. 2 and FIG. 3 respectively show such key figures KFG of acoustic parameters PRM to be displayed to a user USR. The model MDL comprises the object OBJ as a sound emitting engine, the sound source SCR. Near the objects surface, the source SCR a near field singularity problem occurs well visible in the pressure distribution of FIG. 2. FIG. 3 shows the result of applying the Near Field Singularity treatment according to the method of the invention, the pressure distribution PDT shows a smooth and accurate field even close to the model boundary.

The theoretical background, in particular relating to the coordinate transformation CDT is outlined below. For time harmonic acoustic problems, the steady-state acoustic pressure ϕ at any location x in a three-dimensional fluid domain V is governed by the Helmholtz differential equation:

$$\begin{matrix}{∇}^{2} φ ( x ) + {k}^{2} φ ( x ) = 0 , & ∀ x ∈ V\end{matrix} \qquad ( 1 )$$

wherein k=ω/c is the acoustic wave number depending on angular frequency ω and speed of sound c. The Kirchhoff-Helmholtz integral equation, which is used to retrieve acoustic pressure ϕ at a field point, is given as:

$$\begin{matrix}φ ( x ) = {\int }_{S} [ G ( x , y ) \frac{\partial φ ( y )}{\partial {n}_{y}} - \frac{\partial G ( x , y )}{\partial {n}_{y}} φ ( y ) ] d {S}_{y} , & ∀ y ∈ S\end{matrix} \qquad ( 2 )$$

wherein x is the position of the field point and y is the position on the model surface. ny denotes unit normal at the point y. G(x, y) is the Green's function of the Helmholtz equation. For a three-dimensional problems, its formulation is

$$G ( x , y ) = \frac{{e}^{ik ‖ x - y ‖}}{4 π ‖ x - y ‖} \qquad ( 3 )$$

The coordinate transformation for near field singularity for quadrilateral elements is known in the literature as the iterated sinh transformation. If written for a parent quadrilateral element whose coordinates spans [−1, 1] for both directions, the surface integral can be expressed in local coordinates u and v for a general function F as follows:

$$I = {\int }_{- 1}^{1} {\int }_{- 1}^{1} F ( η ( u ) , 𝓋 ( v ) ) Jdudv \qquad ( 4 )$$

wherein J is the Jacobian of the mapping from global coordinates to local coordinates. The projection of the field point in local coordinates are declared as η0 and υ0. A two-level transformation, i.e. the iterative sinh transformation, is applied as follows:

$$η ( u ) = {η}_{0} + {r}_{n} sinh ( m 1 q ( u ) - k 1 ) \qquad ( 5 )$$

$$𝓋 ( v ) = {v}_{0} + {r}_{n} sinh ( m 2 p ( v ) - k 2 ) \qquad ( 6 )$$

wherein rn is the shortest normal distance from the field point to the element surface and where m1, k1, m2 and k2 are defined a:

$$m 1 = 0.5 [ arc sinh ( \frac{1 + {η}_{0}}{{r}_{n}} ) + arc sinh ( \frac{1 - {η}_{0}}{{r}_{n}} ) ] \qquad ( 7 )$$

$$k 1 = 0.5 [ arc sinh ( \frac{1 + {η}_{0}}{{r}_{n}} ) - arc sinh ( \frac{1 - {η}_{0}}{{r}_{n}} ) ] \qquad ( 8 )$$

$$m 2 = 0.5 [ arc sinh ( \frac{1 + {v}_{0}}{{r}_{n}} ) + arc sinh ( \frac{1 - {v}_{0}}{{r}_{n}} ) ] \qquad ( 9 )$$

$$k 2 = 0.5 [ arc sinh ( \frac{1 + {v}_{0}}{{r}_{n}} ) - arc sinh ( \frac{1 - {v}_{0}}{{r}_{n}} ) ] . \qquad ( 10 )$$

To complete the definitions in Eqs. 5 and 6, the variables q(u) and p(v) are required to be defined. To simplify the definitions, some auxiliary variables are declared first:

$$a 1 = k 1 / m 1 \qquad ( 11 )$$

$$b 1 = \frac{π}{4 m 1} \qquad ( 12 )$$

$$a 2 = k 2 / m 2 \qquad ( 13 )$$

$$b 2 = \frac{π}{4 m 2} \qquad ( 14 )$$

$$c 1 = 0.5 [ arc sinh ( \frac{1 + a 1}{b 1} ) + arc sinh ( \frac{1 - a 1}{b 1} ) ] \qquad ( 15 )$$

$$d 1 = 0.5 [ arc sinh ( \frac{1 + a 1}{b 1} ) - arc sinh ( \frac{1 - a 1}{b 1} ) ] \qquad ( 16 )$$

$$c 2 = 0.5 [ arc sinh ( \frac{1 + a 2}{b 2} ) + arc sinh ( \frac{1 - a 2}{b 2} ) ] \qquad ( 17 )$$

$$d 2 = 0.5 [ arc sinh ( \frac{1 + a 2}{b 2} ) - arc sinh ( \frac{1 - a 2}{b 2} ) ] . \qquad ( 18 )$$

By using the above defined auxiliary variables, the definition becomes:

$$q ( u ) = a 1 + b 1 sinh ( c 1 u - d 1 ) \qquad ( 19 )$$

$$p ( v ) = a 2 + b 2 sinh ( c 2 v - d 2 ) \qquad ( 20 )$$

The Jacobian of the transformation is:

$$J = c 1 c 2 {r}_{n}^{2} \frac{{π}^{2}}{16} cosh ( c 1 u - d 1 ) cosh ( c 2 v - d 2 ) cosh ( \frac{π}{4} sinh ( c 1 u - d 1 ) ) cosh ( \frac{π}{4} sinh ( c 2 v - d 2 ) ) \qquad ( 21 )$$

The above transformation is defined for quadrilateral elements but not for triangular elements. To use it for triangular elements, two extra steps are required; one at the start to transform the triangular space to the quadrilateral one, and one at the end to convert the quadrilateral space back to the triangular one. The projection of the field point to the surface element is done via the gradient method. In this process, the derivative of the shape functions of the corresponding element is used, which in this case can be for curved or linear triangular elements. This process provides the local coordinates ξ and σ for a parent triangular element. Next, these local coordinates are transformed to the quadrilateral space. For a Lagrangian element defined in the [−1, 1] space, it is:

$$u = \frac{4 ξ + 2 σ + 2}{2 - 2 σ} \qquad ( 22 )$$

$$v = σ \qquad ( 23 )$$

After this transformation, the process is continued as if the element is a quadrilateral one. Once the coordinate transformations on the quadrilateral space are executed, the local coordinates are transformed back to the triangular space as follows:

$$ξ = \frac{- 2 - 2 η ( u ) 𝓋 ( v ) + 2 η ( u ) - 2 𝓋 ( v )}{4} \qquad ( 24 )$$

$$σ = 𝓋 ( v ) \qquad ( 25 )$$

The Jacobian for the triangular element Jt is updated as:

$${J}_{t} = J \frac{( 2 - 2 𝓋 ( v ) )}{4} \qquad ( 26 )$$

By deploying the extra transformations as defined for triangular elements, a general Near Field Singularity Treatment is defined, which can be used for linear and curved versions of the triangular and quadrilateral elements.

1. A method of determining acoustic parameters of an emission, scattering, or emission and scattering of an object, the method comprising:
defining a model including the object, a sound source, and a surrounding area of modelling, the model including a model mesh comprising elements of respective specific element size and defining field points in a surrounding of the object;
processing the model obtaining a result;
post-processing the result, the post-processing of the result comprising assigning to the field points at least one parameter determined from calculating the Helmholtz-Kirchhoff integral from the result, the post-processing further comprising:
identifying field points as near field singularity field points of potential lower result accuracy;
determining, for the near field singularity field points, respectively, an associated model mesh element, the determining of the associated model mesh element comprising determining a local projection from the near field singularity field point to a surface of the object by calculating a minimum normal distance to the surface of the object, wherein the associated model mesh element is a touchdown point of the local projection;
determining, for the near field singularity field points, respectively, a ratio of the minimum normal distance to the element size of the associated model mesh element; and
calculating a Helmholtz-Kirchhoff integral by:
providing a relation of a quadrature order and the ratio;
determining the respective quadrature order for the near field singularity field points, the determining of the respective quadrature order for the near field singularity field points comprising applying the relation; and
calculating the Helmholtz-Kirchhoff integral from the result.

2. The method of claim 1, further comprising applying a coordinate transformation for solving the integral before calculating the Helmholtz-Kirchhoff integral from the result.

3. The method of claim 2, wherein the model mesh provides triangular object elements, and
wherein the coordinate transformation is combining an iterated sinh transformation method with an additional coordinate transformation projecting the triangular object element space to a quadrilateral object element space.

4. The method of claim 1, wherein the identifying comprises:
defining a threshold distance of the field points to the object; and
assigning the field points to one of two groups:
near field singularity field points that are less than the threshold distance away from the object; or
standard field points that are not near field singularity field points.

5. The method of claim 1, wherein the identifying comprises:
identifying, via an octree-based search algorithm applied to at least a part of the field points, a reduced search space of potential near field singularity field points before the defining of the threshold distance and the assigning of the field points are applied to the reduced search space.

6. The method of claim 1, further comprising:
displaying the acoustic parameters, key figures calculated from the acoustic parameters, or the acoustic parameters and the key figures, or images illustrating the acoustic parameter fields to a user;
providing the acoustic parameters to an iterative object design process for designing acoustic emission; or
a combination thereof.

7. (canceled)

8. A non-transitory computer-readable storage medium that stores instructions executable by one or more processors to determine acoustic parameters of an emission, scattering, or emission and scattering of an object, the instructions comprising:
defining a model including the object, a sound source, and a surrounding area of modelling, the model including a model mesh comprising elements of respective specific element size and defining field points in a surrounding of the object;
processing the model obtaining a result;
post-processing the result, the post-processing of the result comprising assigning to the field points at least one parameter determined from calculating the Helmholtz-Kirchhoff integral from the result, the post-processing further comprising:
identifying field points as near field singularity field points of potential lower result accuracy;
determining, for the near field singularity field points, respectively, an associated model mesh element, the determining of the associated model mesh element comprising determining a local projection from the near field singularity field point to a surface of the object by calculating a minimum normal distance to the surface of the object, wherein the associated model mesh element is a touchdown point of the local projection;
determining, for the near field singularity field points, respectively, a ratio of the minimum normal distance to the element size of the associated model mesh element; and
calculating a Helmholtz-Kirchhoff integral by:
providing a relation of a quadrature order and the ratio;
determining the respective quadrature order for the near field singularity field points, the determining of the respective quadrature order for the near field singularity field points comprising applying the relation; and
calculating the Helmholtz-Kirchhoff integral from the result.

9. A system for determining acoustic parameters of an emission of an object, the system comprising:
at least one processor configured to determine acoustic parameters of an emission, scattering, or emission and scattering of an object, the at least one processor being configured to determine the acoustic parameters of the emission, scattering, or emission and scattering of the object comprising the at least one processor being configured to:
define a model including the object, a sound source, and a surrounding area of modelling, the model including a model mesh comprising elements of respective specific element size and defining field points in a surrounding of the object;
process the model obtaining a result;
post-process the result, the post-process of the result comprising assignment to the field points at least one parameter determined from calculation of the Helmholtz-Kirchhoff integral from the result, the post-process further comprising:
identification of field points as near field singularity field points of potential lower result accuracy;
determination, for the near field singularity field points, respectively, of an associated model mesh element, the determination of the associated model mesh element comprising determination of a local projection from the near field singularity field point to a surface of the object by calculation of a minimum normal distance to the surface of the object, wherein the associated model mesh element is a touchdown point of the local projection;
determination, for the near field singularity field points, respectively, of a ratio of the minimum normal distance to the element size of the associated model mesh element; and
calculation of a Helmholtz-Kirchhoff integral by:
provision of a relation of a quadrature order and the ratio;
determination of the respective quadrature order for the near field singularity field points, the determination of the respective quadrature order for the near field singularity field points comprising application of the relation; and
calculation of the Helmholtz-Kirchhoff integral from the result.
